(19) United States
(12) Patent Application Publication
(10) Pub. No.: US 2026/0213770 A1
(43) Pub. Date: Jul. 23, 2026

(54) BIT ERROR RATE REDUCTION METHOD FOR RECONFIGURED GPS CNAV-2 NAVIGATION MESSAGE

(71) Applicant: ESKISEHIR TEKNIK UNIVERSITESI, ESKISEHIR (TR)

(72) Inventors: Hakan Oktal, ESKISEHIR (TR); AHMET ESAT SÜZER, ANKARA (TR)

(21) Appl. No.: 18/876,434

(22) PCT Filed: Dec. 22, 2023
(86) PCT No.: PCT/TR2023/051663

§ 371 Date: Dec. 18, 2024

(51) Int. Cl. H03M 13/09

(52) U.S. Cl. CPC H03M 13/09

(57) ABSTRACT

The invention relates to a bit error rate reduction method for reconfigured GPS CNAV-2 navigation message, by using the CRC-POLAR channel coding method instead of BCH and LDPC as the channel coding method to capture and correct errors caused by ambient noise

### TECHNICAL FIELD OF THE INVENTION

The invention relates to a bit error rate reduction method for reconfigured GPS CNAV-2 navigation message. This method is more resistant to ambient noise and has a much lower bit error rate (BER) by simply changing the channel coding method used in the existing CNAV-2 message structure, without interfering with the message content and structure.

### STATE OF THE ART

It is possible to define the navigation message broadcast by satellites such as GPS and global positioning systems (GNSS: Global Navigation Satellite System) as an information package that allows the user to calculate quantities such as location, time and speed. Since the receiver calculates its position, i.e. latitude, longitude and altitude, by analysing the data bits received from at least four different visible satellites, the navigation message has a direct impact on the receiver position determination. Any error in the navigation message, especially due to ambient noise, prevents the incoming data from being accurate and reliable. In order to minimize this situation and increase the reliability of the incoming navigation message and ensure more accurate analysis, channel coding methods are used in satellite positioning systems, as in many communication systems. In other words, receiving the navigation message, which is vital for receivers in GNSS, more accurately and safely is directly related to the error correction ability of the channel codes. Therefore, channel coding methods used to detect and correct errors in the navigation message are among the structures that need modernization to increase position accuracy in GNSS. Civil Navigation 2(CNAV-2 ) message is the agreed upon navigation message format that will be broadcast not only from GPS but also from three other global positioning systems such as GLONASS, Galileo and Beidou-3.

The invention subject to the application numbered “CN113541914A” in the known state of the art proposes a CNAV-2 message frame synchronisation method based on association rules, which is used to solve the poor error resistance performance of the existing CNAV-2 message frame.

The invention, which is the subject of the state of the art with application number “US2008228398A1”, relates to the field of navigation using GNSS (e.g. GPS) and especially assisted GNSS (e.g. assisted GPS). It also relates to a module for use in a mobile station having a GPS receiver (or an A-GPS receiver) or a mobile Location Centre (SMLC) in service to determine an ITOW for a CNAV-1 signal.

When the state of the art is examined, the next generation CNAV-2 message to be broadcast from all global satellite navigation systems such as GPS, GLONASS, Galileo and Beidou-3 consists of 1800 bit, 18 second frames and three sub-frames of different lengths, each frame containing different information. BCH (Bose-Chaudhuri-Hochquenghem) and LDPC (Low Density Parity Check) methods are used as channel coding methods to capture and correct errors caused by ambient noise. Then, the second and third subframes are combined with the bit interleaving technique. CRC-Polar coding and QC-LDPC methods, which are especially popular with the 5G communication system in recent years, are more advanced and have better performance than other channel coding methods. A study evaluating the performance of these methods when adapted to the CNAV-2 message and improving the above-mentioned message structure is not included in the known state of the art. For this reason, it is important to develop a message structure that is more resistant to ambient noise and has a much lower Bit Error Rate (BER) by changing only the channel coding method without interfering with the existing message content and structure.

As a result, due to the abovementioned disadvantages and the insufficiency of the current solutions regarding the subject matter, a development is required to be made in the relevant technical field.

### AIM OF THE INVENTION

The invention relates to a reconfigured GPS CNAV-2 navigation message bit error rate reduction method, which is more resistant to ambient noise and has a much lower bit error rate by simply changing the channel coding method used in the existing CNAV-2 message structure, without interfering with the message content and structure.

The most important aim of the invention is to provide better noise resistance and better performance without changing the message structure

Another aim of the invention is to provide a message structure that is more resistant to ambient noise and has a much lower Bit Error Rate (BER) by changing only the channel coding method without interfering with the existing message content, structure and message length.

### DESCRIPTION OF THE INVENTION

The invention relates to a reconfigured GPS CNAV-2 navigation message bit error rate reduction method, which is more resistant to ambient noise and has a much lower bit error rate by simply changing the channel coding method used in the existing CNAV-2 message structure, without interfering with the message content and structure, In the light of seven benchmarks, namely coding complexity, decoding complexity, coding time, decoding time, block length, code rate and Bit Error Rate (BER), a message structure has been developed for the new generation GPS CNAV-2 message structure depending on the ambient noise, without changing the existing message content and structure by using the CRC-Polar error capture and correction technique, which is especially preferred in innovative communication systems, with high accuracy and noise resistance.

Under the improvement heading, a reconstructed GPS CNAV-2 navigation message bit error rate reduction method with better bit error rate (BER) performance has been developed by applying the CRC-Polar method, which is a combination of 24-bit CRC polynomial and Polar coding, instead of the existing BCH and LDPC techniques. In the reconfigured GPS CNAV-2 navigation message bit error rate reduction method; the next generation CNAV-2 message to be broadcast from all global satellite navigation systems such as GPS, GLONASS, Galileo and Beidou-3 consists of 1800 bit, 18 second frames and three sub-frames of different lengths, each frame containing different information. CRC-Polar channel coding method is used instead of BCH and LDPC as channel coding method to detect and correct errors caused by ambient noise. In the first subframe (SF1), the CRC-Polar method was applied using 9-bit TOI (Time of Interval) data and 24-bit CRC polynomial. In the second subframe, a 1200-bit CRC-polar method was implemented using a 24-bit CRC polynomial with 576-bit orbit and clock parameters. In the third subframe, a 548-bit CRC-polar method is implemented using 250-bit variable data and a 24-bit CRC polynomial. Then, the second and third subframes are combined with the bit interleaving technique. When combined, a 52-bit TOI and a 1748-bit navigation message are created. In this way, a message structure that is more resistant to ambient noise and has a much lower Bit Error Rate (BER) has been developed by changing only the channel coding method without interfering with the existing message content and structure.

The reconfigured GPS CNAV-2 navigation message bit error rate reduction method consists of the following processing steps performed by the satellite and GNSS receiver;
Generation of CNAV-2 navigation message to be broadcast from four global positioning systems,
Applying CRC-Polar method using 24-bit CRC polynomial with 9-bit TOI in the first subframe (SF1)
Applying 1200-bit CRC-polar method using a 24-bit CRC polynomial with 576-bit orbit and clock parameters in the second subframe,
Applying 548-bit CRC-polar method is implemented using 250-bit variable data and a 24-bit CRC polynomial in the third subframe,
Combining the second and third subframes with the bit interleaving technique,
When combined, creating 52-bit TOI and 1748-bit navigation message.

The application of the CRC-Polar method results in gains of 0.9 dB at 10⁻³ BER for sub-frame 1, 0.72 dB and 1.63 dB for sub-frame 2 and sub-frame 3 at 10⁻² BER. In this case, if the CNAV-2 message structure obtained by using the CRC-Polar method, which performs very well in each sub-frame to improve the performance of the CNAV-2 message without changing the same, there is no need for any other changes other than changing the coding method in the CNAV-2 message. The integration of this proposal to improve the noise robustness of the signal into the existing system is quite easy and low cost.

1. Reconfigured GPS CNAV-2 navigation message bit error rate reduction method, characterized by comprising the following process steps performed by satellite and GNSS receiver
Generation of CNAV-2 navigation message to be broadcast from four global positioning systems,
Applying CRC-Polar method using 24-bit CRC polynomial with 9-bit TOI in the first subframe (SF1)
Applying 1200-bit CRC-polar method using a 24-bit CRC polynomial with 576-bit orbit and clock parameters in the second subframe,
Applying 548-bit CRC-polar method is implemented using 250-bit variable data and a 24-bit CRC polynomial in the third subframe,
Combining the second and third subframes with the bit interleaving technique,
When combined, creating 52-bit TOI and 1748-bit navigation message.
